(19) United States
(12) Patent Application Publication
(10) Pub. No.: US 2011/0057736 A1
(43) Pub. Date: Mar. 10, 2011

(54) Linear, Voltage-Controlled Ring Oscillator With Current-Mode, Digital Frequency And Gain Control

(75) Inventor: Dean A. Badillo, Laguna Beach, CA (US)

(73) Assignee: SKYWORKS SOLUTIONS, INC., Woburn, MA (US)

(21) Appl. No.: 12/944,839

(22) Filed: Nov. 12, 2010

Related U.S. Application Data
(63) Continuation of application No. PCT/US2009/041919, filed on Apr. 28, 2009.

(51) Int. Cl. H03K 3/03

(52) U.S. Cl. 331/57

(57) ABSTRACT

In a voltage-controlled ring oscillator, one or more controllable current sources generate a bias current in response to a tuning voltage. Any of several features can be included to promote frequency tuning linearity. In accordance with one feature, the ring oscillator circuit transistors can be sized relative to one another to skew the rise and fall times of the ring oscillator output signal with respect to one another. In accordance with another feature, a peak limiter can limit the oscillation amplitude in response to the bias current. In accordance with still another feature, a controllable bias current source can include a voltage-to-current converter and one or more groups of digitally controlled current source transistors.

### CROSS-REFERENCE TO RELATED APPLICATION

This application is filed under 35 U.S.C. 111(a) as a continuation of International Patent Application Serial No. PCT/US2009/041919, entitled “Linear, Voltage-Controlled Ring Oscillator With Current-Mode, Digital Frequency And Gain Control” and filed on Apr. 28, 2009 (Applicant: Skyworks Solutions, Inc. et al.; Attorney Docket No. 19308.0164P1), which International Patent Application designates the United States and is hereby incorporated by reference in its entirety.

### BACKGROUND

The circuitry of essentially every digital and mixed-signal integrated circuit (IC) requires one or more clock signals. Circuitry for generating clock signals commonly includes one or more oscillators. An oscillator can be of the fixed or controllable type. A fixed oscillator is an autonomous circuit that generates a signal of a single, precise frequency. A controllable oscillator produces a signal of frequency that is proportional to an external tuning signal, allowing the oscillator to cover a range of frequencies. Regardless of the type of oscillator, inevitable variations in the manufacturing process, supply voltage, and operating temperature (PVT) result in frequency error. The conventional method of compensating for these effects is to add frequency tuning to a fixed oscillator or to increase the existing tuning range of a controllable oscillator by an amount equal to the expected error. Then, a feedback or calibration system can be used to generate a tuning signal and correct the oscillator frequency. Oscillator gain, K_{osc}, is the degree by which a tuning signal can adjust the frequency,

$$Oscillator Gain ≡ {K}_{OSC} = \frac{Change in Freqeuncy}{Change in Tuning Signal} . \qquad ( 1 )$$

Therefore, increasing the frequency range of an oscillator for a given tuning signal also increases the gain. Depending on the application in which the oscillator is to be used, this solution may not be acceptable or create undesirable side effects. For example, in a phase-locked loop (PLL), the forward gain of the PLL is distributed between the oscillator, phase detector and loop filter. If the loop gain is to remain constant, increasing the oscillator gain must be accompanied by a decrease in phase detector or loop filter gain, which can increase in-band noise. Another drawback of increasing oscillator gain is a greater sensitivity to any noise coupling onto the tuning port. This will modulate the oscillator, causing sidebands to appear in the output spectrum that can degrade performance in many applications. Finally, most methods of frequency control are linear over a narrow range only. Nonlinear behavior resulting from increasing this range can cause the oscillator to be over or under corrected.

Although various oscillator circuits are known, a type known as a ring oscillator is commonly used in IC applications because ring oscillators generally occupy less IC die area than similar oscillators that are based upon inductive or capacitive elements. Ring oscillators rely on the distributed phase shift and gain of multiple amplifiers connected in a closed loop to generate oscillation. As illustrated in FIG. 1A, an exemplary ring oscillator 10 can comprise three inverters 12, 14 and 16 connected in series with each other, with the output of each of inverters 12, 14 and 16 coupled to an input of another one of inverters 12, 14 and 16, i.e., in a ring. Although three inverters 12, 14 and 16 are shown in this example, a ring oscillator can comprise any number of inverters. Capacitances 18, 20 and 22 represent the capacitances between the nodes 24, 26 and 28 at the outputs of the respective inverters with respect to a common node 30. Each of capacitances 18, 20 and 22 has a value (i.e., a capacitance) of C1. That is, the total capacitance experienced by each of inverters 12, 14 and 16 at their respective output nodes 24, 26 and 28 is C1.

As illustrated by the waveform diagram of FIG. 1B, ring oscillator 10 oscillates because a net DC phase shift of 180° is present, and an additional phase shift of 60° per inverter occurs at a frequency where the total gain around the ring is unity. The waveform shown in FIG. 1B is based upon several assumptions (i.e., simplifications made for explanatory clarity) about ring oscillator 10. First, the signals at nodes 24, 26 and 28 do not begin to transition until the respective inverter input signal crosses the triggering threshold (indicated in dashed line), which in this example is VDD/2 (where VDD represents a fixed power supply voltage). Second, rise and fall times, tᵣ and t_{f}, are equal. Finally, slewing is linear.

The frequency of the oscillator shown in FIG. 1A can be expressed in terms of rise and fall times by recognizing that a cycle comprises a rising edge, a falling edge, a peak and a trough. As the first of the above-mentioned assumptions or simplifications is that an inverter input signal must reach VDD/2 before any change in the inverter output signal can occur, the flat peak of the signal at node 26 can be attributed to the time need for the signal at node 24 to rise from ground to the triggering threshold. Consequently, the duration of this peak is equal to half of the rise time. Likewise, the flat trough of signal 26 is determined by the time needed for the signal at node 24 to drop from VDD to the triggering threshold and is equal to half the fall time. Summing these times yields a frequency of

$${f}_{0} = \frac{1}{{t}_{r} + {t}_{f} + \frac{1}{2} {t}_{r} + \frac{1}{2} {t}_{f}} = \frac{1}{\frac{3}{2} ( {t}_{r} + {t}_{f} )} . \qquad ( 2 )$$

The frequency of ring oscillator 10 can also be expressed in terms of the delay associated with each inverter, t_{d} (labeled “td” in FIG. 1B to aid readability). The delay is defined as the interval between input and output threshold crossings. It can be noted that the delay depends on whether the inverter is driven by a rising, t_{dr}, or falling edge, t_{df}. The two are only equal when the rise and fall times are equal, that is, t_{dr}=t_{df}≡t_{d} when tᵣ=t_{f}, as in this example. Using this definition, the frequency of ring oscillator 10 can alternatively be expressed as

$${f}_{0} = \frac{1}{2 {nt}_{d}} . \qquad ( 3 )$$

In equation (3), n is the number of stages, and the division by two reflects the fact that the signal must circulate around the ring twice before it completes a full cycle. Equating equations (2) and (3) for n=3 gives t_{d}=¼(tᵣ+t_{f}). As linear and identical slew rates are assumed in this example, a third frequency formula can be written by substituting tᵣ=t_{f}=V_{DD}C1/I into equation (2):

$${f}_{0} = \frac{I}{3 {V}_{DD} C 1} \qquad ( 4 )$$

where I is the charging/discharging output current of each of inverters 12, 14 and 16.

As reflected in equation (4), it is known to control ring oscillator frequency by manipulating one or more of the current, the voltage swing or the capacitance.

As shown in FIG. 2, one known method for providing increased frequency tuning range in a ring oscillator by manipulating capacitance involves including a network of binary-weighted, digitally programmable, switched capacitors 30-46 at the inverter output nodes to increase the tuning range. With the inclusion of capacitors 30-46, the frequency of ring oscillator 10′ becomes

$$f ( {V}_{tune} , d ) = \frac{I ( {V}_{tune} )}{3 {V}_{DD} ( C 1 + {dC}_{LSB} )} \qquad ( 5 )$$

where “C_{LSB}” corresponds to the amount of capacitance added to the output of each of inverters 12′, 14′ and 16′ for a unit decrease in the digital control word d (i.e., the least-significant bit (LSB) of d). This capacitance, C_{LSB}, is represented by capacitors 34, 40 and 46 in FIG. 2. In equation (5), and with reference to FIG. 2, I is assumed to be a function of the analog tuning voltage, Vₜᵤₙₑ, the number of capacitors in the array are m, and the digital word allowing the array to function as a programmable load is d. In FIG. 2, the least significant bit of this digital word d is labeled “d[0],” the next most-significant bit is labeled “d[1],” etc., through the most-significant bit “d[m−1].” Solving equation (5) for a range of values of Vₜᵤₙₑ produces a continuous range of frequencies referred to as a tuning curve. The position of the tuning curve depends on d. Tuning curves for all possible values of d in this example, i.e., d=0 through d=2^{m}−1, yields a “family” of curves, as illustrated in FIG. 3.

It is assumed in FIG. 3 that the current is a linear function of Vₜᵤₙₑ; however, this is not always the case. When d=0, all of the switched capacitors 30-46 are disconnected, and the original tuning range, f′(max)≦f≦f(min), is retained. The gain for this setting, K_{vco}(0), is identical to that of ring oscillator 10 described above with regard to FIG. 1, i.e., without switched capacitors 30-46. Using the digitally controlled capacitors 30-46, the tuning range is expanded to f(min)≦f≦f(max). Therefore, adding digitally programmable, switched capacitors 30-46 significantly increases the tuning range. Although in the example shown in FIG. 3 the tuning curve only moves lower in frequency, in practice a ring oscillator circuit can be designed to oscillate at the desired or selected frequency when Vₜᵤₙₑ is centered and d=2^{m-1}. Then the expanded tuning range that is added by the switched capacitors can be used to correct positive and negative frequency variations.

Although ring oscillator 10 shown in FIG. 2 is an improvement over simply increasing the analog tuning range, there are significant drawbacks. A major drawback is the added IC die area consumed by the switched capacitors 30-46. Note that a capacitor array is needed for each of the n stages, multiplying the area cost by n as well. An often overlooked but potentially serious penalty for such enormous circuit growth is the parasitic capacitance associated with interconnecting the capacitor arrays. For high frequency oscillators, this unanticipated load can be extremely problematic.

Another disadvantage stems from the nonlinear nature of using capacitance as a method of frequency control. As capacitance is in the denominator of equation (5), its relationship to frequency is on the order of 1/x. This causes more significant bits to produce progressively smaller frequency shifts. This behavior is reflected in FIG. 3 by the tuning curves moving closer together as d increases. The nonlinear behavior of switching capacitance also affects the gain of the oscillator, which is determined by taking the partial derivative of the frequency with respect to the tuning voltage,

$${K}_{VCO} ( d ) = \frac{\partial {f}_{0} ( {V}_{tune} , d )}{\partial {V}_{tune}} = \frac{α}{3 {V}_{DD} ( C 1 + {dC}_{LSB} )} . \qquad ( 6 )$$

In equation (6) the assumption of linear voltage-to-current conversion is maintained, and a represents the constant transconductance. In equation (6) K_{vco}, varies inversely with the amount of switched capacitance programmed into the circuit. In FIG. 3 this result is expressed as a decrease in slope of tuning curves as d increases. In other words, K_{vco}(0)>K_{vco}(2^{m}−1).

As noted above with regard to equation (4), it is also known to control ring oscillator frequency by manipulating the current. As illustrated in FIG. 4A, a known method for providing increased frequency tuning range in a ring oscillator by manipulating current involves combining a ring oscillator 50 with a programmable switched-resistor-based voltage-to-current converter 52. A resistance R is provided by a number of series-connected switched resistances 54, 56, 58, etc. The resistance R is coupled to the drain of a transistor 60 and an input of an operational amplifier (op-amp) 62. The other input of op-amp 62 receives the tuning voltage signal Vₜᵤₙₑ. The drain current of transistor 60, I_{D}=Vₜᵤₙₑ/R, can be programmed by setting the switched resistances 54, 56, 58, etc., to result in a selected value of R. This drain current I_{D} is mirrored by two other transistors 64 and 66 to bias ring oscillator 50. An advantage of this current-based approach over the above-described capacitance-based approach is that less IC die area is required due to the circuit not needing to be replicated n times. However, since the bias current is inversely proportional to the resistance, this method, in which bias current is indirectly adjusted by setting resistor values, suffers from the same nonlinearity as the capacitor-based approach described above with regard to FIG. 2. Furthermore, duplicating the family of tuning curves attained by using switched-capacitor networks with switched bias currents requires attention to subtle circuit design details within the ring oscillator itself, if good linearity is to be maintained.

It would be desirable to provide a voltage-controlled ring oscillator having a large frequency tuning range without sacrificing linearity or IC die area efficiency. The present invention addresses these concerns and others in the manner described below.

### SUMMARY

Embodiments of the invention relate to a voltage-controlled ring oscillator in which one or more controllable current sources generate a ring oscillator bias current in response to a tuning voltage. Controlling current sources directly rather than controlling a resistance or capacitance can promote frequency tuning linearity.

In accordance with a feature that can be included in embodiments of the invention, the ring oscillator circuit transistors can be sized relative to one another to skew the rise and fall times of the ring oscillator output signal with respect to one another. For example, the rise time can be significantly greater than the fall time. Such skewing can promote frequency tuning linearity.

In accordance with another feature that can be included in embodiments of the invention, a peak limiter can limit the oscillation amplitude in response to the bias current. Such limiting can promote frequency tuning linearity.

In accordance with still another feature that can be included in embodiments of the invention, a controllable current source can include a voltage-to-current converter and one or more groups of digitally controlled current source transistors. The current source transistors can receive a current from the voltage-to-current converter and produce an output current in response. The output current produced by such a group of digitally controlled current source transistors can be used to bias the oscillator circuit, a peak limiter (in an embodiment in which a peak limiter is included), or both.

Other systems, methods, features, and advantages of the invention will be or become apparent to one with skill in the art upon examination of the following figures and detailed description. It is intended that all such additional systems, methods, features, and advantages be included within this description, be within the scope of the invention, and be protected by the accompanying claims.

### BRIEF DESCRIPTION OF THE FIGURES

The components within the figures are not necessarily to scale, emphasis instead being placed upon clearly illustrating the principles of the invention. Moreover, in the figures, like reference numerals designate corresponding parts throughout the different views.

FIG. 1A is a circuit diagram of a ring oscillator in accordance with the prior art.

FIG. 1B is a waveform diagram showing waveforms of signals during operation of the ring oscillator of FIG. 1.

FIG. 2 is a block diagram of a ring oscillator that includes switched capacitors, in accordance with the prior art.

FIG. 3 is a plot showing oscillation frequency (f) versus voltage (V) for various settings of the switched capacitors of the ring oscillator of FIG. 2.

FIG. 4 is a circuit diagram of a ring oscillator that includes switched resistances for generating selectable a ring oscillator bias current, in accordance with the prior art.

FIG. 5 is a circuit diagram of a voltage-controlled ring oscillator in accordance with an exemplary embodiment of the invention.

FIG. 6 is a waveform diagram showing waveforms of signals during operation of the ring oscillator of FIG. 5.

FIG. 7 is a circuit diagram showing the ring oscillator of FIG. 5 in further detail.

FIG. 8A is a waveform diagram showing the operation of the peak limiter in the ring oscillator of FIGS. 5 and 7.

FIG. 8B is a partial circuit diagram showing currents in a first region of operation of the peak limiter in the ring oscillator of FIGS. 5 and 7.

FIG. 8C is a partial circuit diagram showing currents in a second region of operation of the peak limiter in the ring oscillator of FIGS. 5 and 75.

FIG. 8D is a partial circuit diagram showing currents in a third region of operation of the peak limiter in the ring oscillator of FIGS. 5 and 7.

FIG. 9A illustrates a family of tuning curves representing various operational settings of the ring oscillator of FIGS. 5 and 7.

FIG. 9B is similar to FIG. 9A and illustrates another family of tuning curves representing various other operational settings of the ring oscillator of FIGS. 5 and 7.

### DETAILED DESCRIPTION

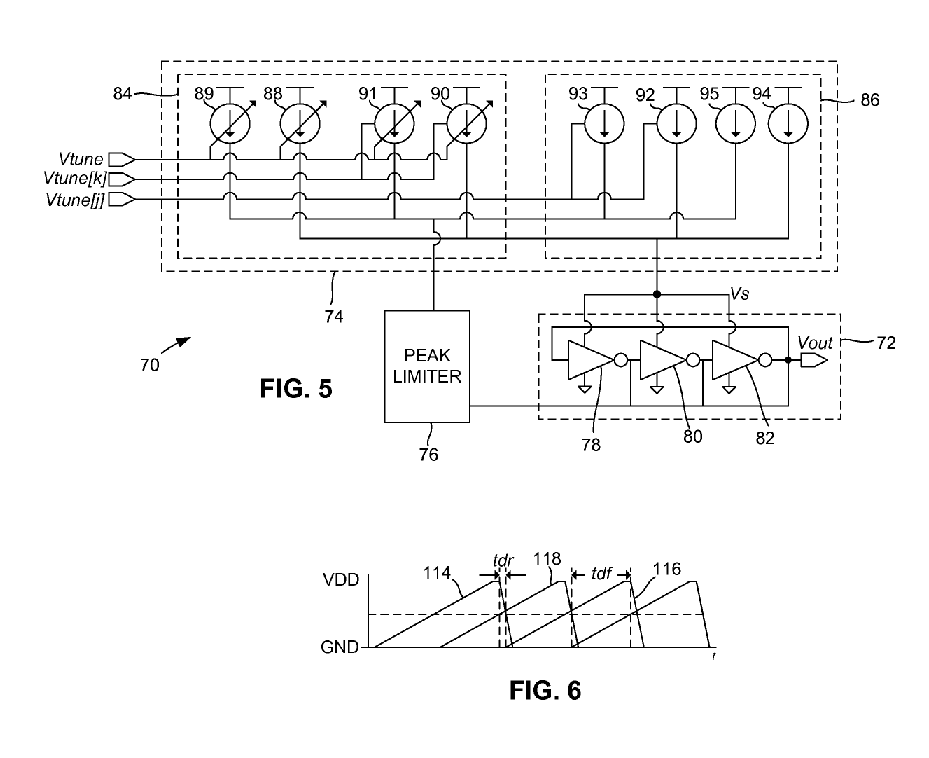

As illustrated in FIG. 5, in accordance with an illustrative or exemplary embodiment of the invention, a voltage-controlled ring oscillator 70, which can be provided in integrated circuit (IC) form, provides analog and digital frequency tuning in the current domain as well as selectable combinations of gain and frequency range. As illustrated in FIG. 5, voltage-controlled ring oscillator 70 comprises or includes a ring oscillator circuit 72, a bias current generator 74, and a peak limiter 76. Although in the exemplary embodiment ring oscillator circuit 72 includes three inverters 78, 80 and 82 for purposes of illustration, in other embodiments such a ring oscillator circuit can include any number of inverters or similar circuits.

Bias current generator 74 includes a programmable tuning current (PTC) source 84 and a programmable fixed current (PFC) source 86. PTC source 84 includes first and second controllable, i.e., variable, full current sources 88 and 90, and first and second controllable scaled current sources 89 and 91. First controllable full current source 88 can be controlled in response to the analog tuning voltage signal Vₜᵤₙₑ (labeled “Vtune” in the drawing figures to aid readability). That is, first controllable full current source 88 produces a current having a magnitude that reflects the selected value of Vₜᵤₙₑ. First controllable scaled current source 89 produces a scaled-down version of the current that first controllable full current source 88 produces. Similarly, second controllable full current source 90 can be controlled in response to both Vₜᵤₙₑ and a digital tuning signal Vₜᵤₙₑ[k]. Second controllable scaled current source 91 produces a scaled-down or proportional version of the current that second controllable full current source 90 produces. PFC source 86 includes a controllable full current source 92 that can be controlled in response to another digital tuning signal Vₜᵤₙₑ[j] and a fixed full current source 94 that produces a fixed or constant current. PFC source 86 further includes a controllable scaled current source 93 that produces a scaled-down version of the current that controllable full current source 92 produces and a fixed scaled current source 95 that produces a scaled-down or proportional version of the current that fixed full current source 94 produces. The sum of the (full) currents generated by PTC source 84 and PFC source 86 defines a bias current that is provided to each of inverters 78, 80 and 82 of ring oscillator circuit 70. The sum of the scaled-down versions of those currents is provided to peak limiter 76. The total bias current provided to peak limiter 76 is thus proportional to the total bias current provided to ring oscillator circuit 70.

Both digital and analog inputs are provided so that the bias current can be adjusted or varied in a flexible manner by adjusting the analog tuning voltage signal Vₜᵤₙₑ to a selected value while holding the digital values of Vₜᵤₙₑ[j] and Vₜᵤₙₑ[k] constant. Although this exemplary mode of operation is contemplated and discussed in further detail below, it should be noted that any of Vₜᵤₙₑ, Vₜᵤₙₑ[j] and Vₜᵤₙₑ[k] can be adjusted alone or in combination with each other or with other signals in any suitable manner Also, it should be noted that even though PFC source 86 can be controlled or varied in response to Vₜᵤₙₑ[j], the term “fixed” is not intended to be limiting and is used only for purposes of convenience of description, in view of the exemplary mode of operation in which Vₜᵤₙₑ[j] is held constant or fixed while Vₜᵤₙₑ is adjusted.

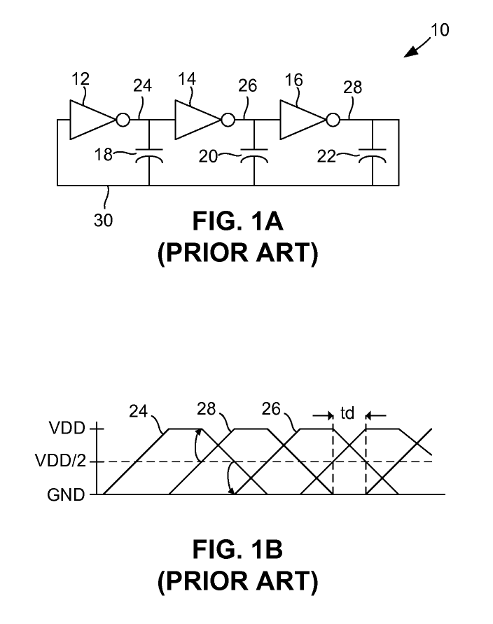

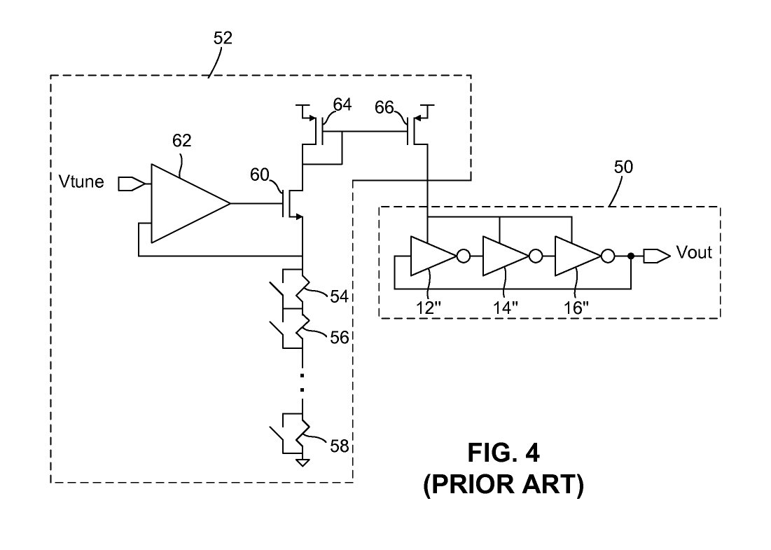

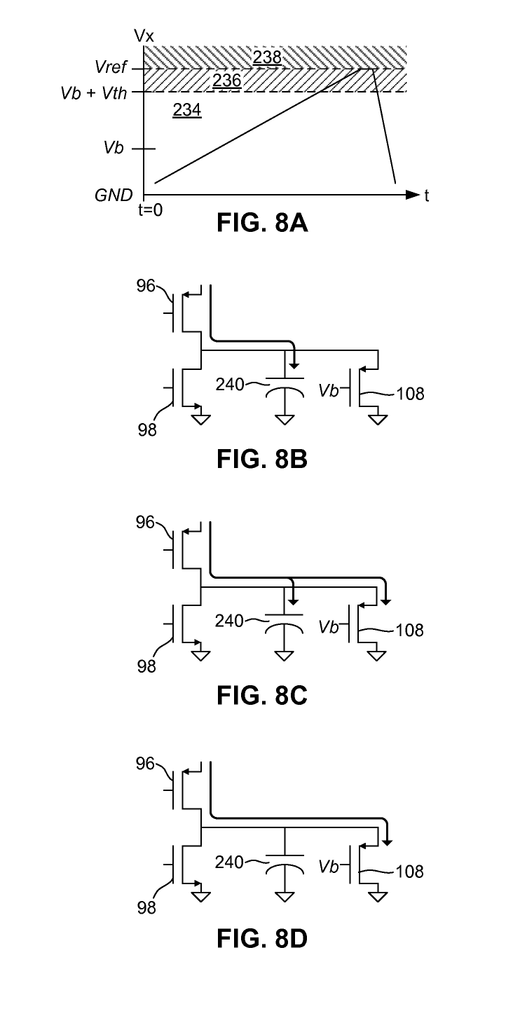

As ring oscillator circuit 70 is current biased, its “supply voltage,” Vₛ (labeled “Vs” in FIG. 5 to aid readability), is the product of the bias current received from bias current generator 74 and the equivalent time-varying impedance of inverters 78, 80 and 82 in parallel. Consequently, this supply voltage and the ring oscillation amplitude tend to follow movements in the bias current. This behavior can be compared with the prior ring oscillator 10 described above with regard to FIG. 1, which is biased with an ideal supply voltage and will therefore oscillate at an amplitude approximately equal to that supply voltage. In the derivations described above with regard to FIGS. 1-4, constant oscillation amplitude is assumed irrespective of bias current. As it is desirable to maintain a constant oscillation amplitude in order to promote tuning linearity, peak limiter 76 is employed to maintain the oscillation amplitude at a level below that of the minimum Vₛ. The operation of peak limiter 76 is described below in further detail with regard to FIGS. 8A-8D.

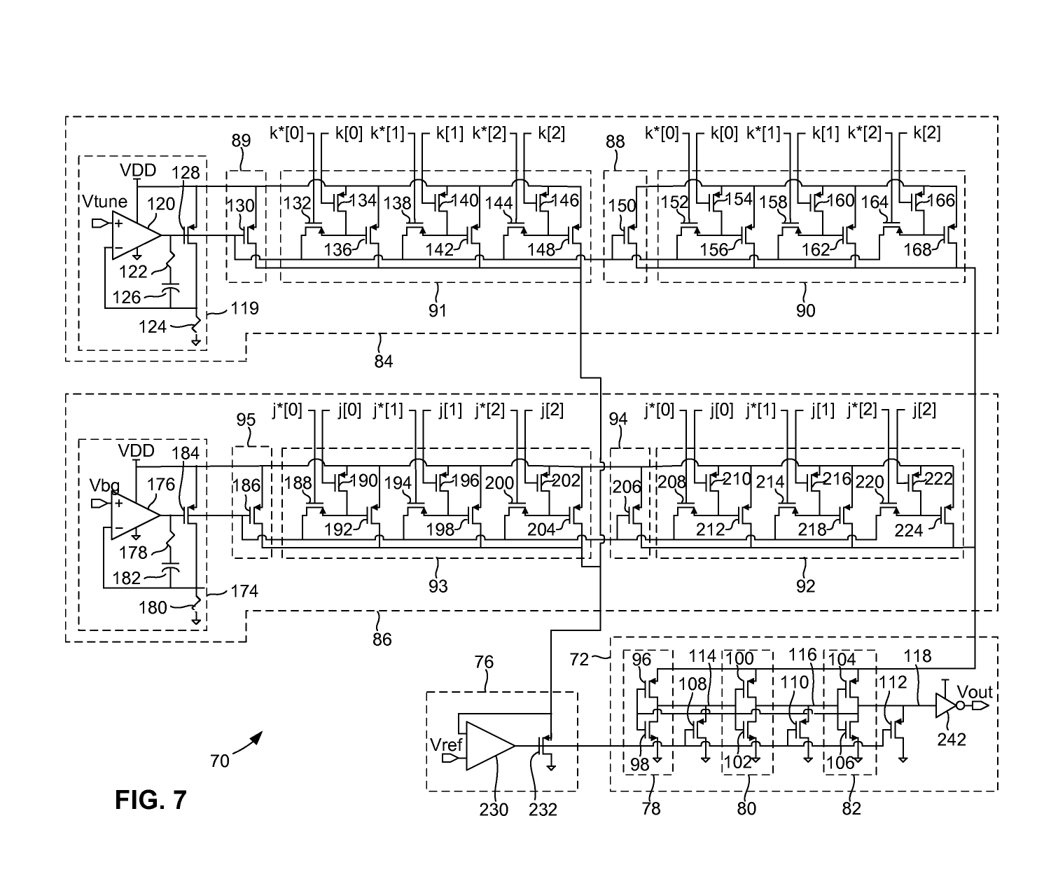

As illustrated in FIG. 7, in ring oscillator circuit 72, inverter 78 includes a PFET 96 and a corresponding NFET 98, inverter 80 includes a PFET 100 and a corresponding NFET 102, and inverter 82 includes a PFET 104 and a corresponding NFET 106. The source terminal of each of PFETs 96, 100 and 104 is connected to the output of PTC source 84 and PFC source 86 to receive the bias current. Ring oscillator circuit 72 further includes PFETs 108, 110 and 112, each of which has a source terminal connected to one of the ring oscillator nodes 114, 116 and 118, respectively.

The transistor arrangement of ring oscillator circuit 72 in which the source terminals of PFETS 96, 100 and 104 receive the bias current provides control over the charging current available to each of inverters 78, 80 and 82 but not the discharge current. In other words, this transistor arrangement allows control of the oscillation signal rise time tᵣ but not the oscillation signal fall time t_{f}. To facilitate control over the oscillation signal fall time t_{f}, a means for skewing the oscillation signal rise and fall times can be provided such that, for example, the oscillation signal rise time tᵣ is substantially greater than the oscillation signal fall time t_{f}, i.e., tᵣ>>t_{f}. It is known that the oscillation signal rise and fall times in a ring oscillator are dependent upon the sizes of the NFET and PFET, i.e., the area of the integrated circuit die on which they are formed, relative to one another. It is also known that for the oscillation signal rise time tᵣ and fall time t_{f} to be equal to one another, the ratio between PFET area and NFET area should be about 3:1, because PFET mobility and thus transconductance is approximately one-third that of an NFET. In the exemplary embodiment, rise and fall times can be skewed by sizing the NFET substantially larger than the corresponding PFET.

With regard to FIG. 7, in forming each of NFETs 98, 102 and 106 and PFETs 96, 100 and 104 on respective areas of the integrated circuit die (not shown for purposes of clarity), a ratio of the area occupied by a PFET to the area occupied by the corresponding NFET can be less than 3:1. For example, the ratio can be about 1:1. Accordingly, PFET transconductance is approximately ⅓ NFET transconductance, resulting in a longer rise time tᵣ than fall time t_{f}. Although in the exemplary embodiment the PFET-to-NFET size ratio is less than about 3:1 (e.g., about 1:1), in other embodiments it can be any suitable number that results in substantially unequal or skewed rise and fall times. Thus, for example, the PFET-to-NFET size ratio can be any that is substantially less than 3:1. The term “substantially” as used herein means by an amount greater than that which would typically occur as a result of unintended, insubstantial variances in IC fabrication process, ambient temperature, etc. Also, in selecting the PFET and NFET sizes, each of inverters 78-82 should have a mean inverter delay, ½(t_{dr}+t_{df}), that is substantially the same as the delay would be if the inverter were to have a PFET-to-NFET size ratio of about 3:1. Exemplary waveforms at nodes 114, 116 and 118 that can result from skewing the inverter rise and fall times in this manner are shown in FIG. 6.

In view of the skewed rise and fall times, the oscillation frequency can be expressed as

$${f}_{0} = \frac{1}{\frac{3}{2} ( {t}_{r} + {t}_{f} )} \approx \frac{3}{2 {t}_{r}} , {t}_{r} >> {t}_{f} . \qquad ( 7 )$$

In equation (7) the constant 3/2 becomes an approximation due to a slight lowering of the threshold voltage associated with the unequal PFET and NFET sizes. Because each cycle is now dominated by a long rise time, controlling this duration via charging current results in linear tuning As tᵣ=V_{sw}C/I_{bias}, and as I_{bias} in the exemplary embodiment is the output of current sources 88-94, V_{sw} in the exemplary embodiment is the peak-to-peak voltage set by peak limiter 76 at each of nodes 114, 116 and 118. It can thus be appreciated that peak limiting and skewing promote linearity of current-mode frequency tuning. (It should be noted that although both peak limiting and skewing are included in the exemplary embodiment, in other embodiments including only one or the other can still promote linearity.) Substituting the above-referenced relation into (6), the oscillation frequency becomes

$${f}_{0} \approx \frac{3 {I}_{bias}}{2 {V}_{sw} C} \qquad ( 8 )$$

An added benefit of skewing the rise and fall times emerges in considering phase noise. Popular theory suggests that the upconversion of flicker noise is increased as waveform symmetry is decreased. However the flicker noise of deep submicron NFETs is several times greater than that of similarly sized PFETs. Comparing the phase noise of a symmetric oscillator with a skewed oscillator at the same frequencies and power consumption reveals that the reduction in flicker noise achieved by increasing/decreasing the size of the NFETs/PFETs overrides any increase in upconversion due to asymmetry. Therefore, in deep submicron IC process, skewing may offer better phase noise performance than a symmetric approach.

With reference again to FIG. 7, PTC source 84 includes a voltage-to-current converter 119 comprising an operational amplifier (op-amp) 120, resistors 122 and 124, a capacitor 126, and a PFET 128. The analog tuning voltage Vₜᵤₙₑ is sensed at the positive input terminal of op-amp 120. The output of op-amp 120 is applied to the gate terminal of PFET 120, the drain terminal of which is connected to resistor 122. The voltage across resistor 124 (the resistance of which can be designated “R₁₂₄”) is applied to the negative terminal of op-amp 120 to complete a unity gain feedback loop. The drain current I_{D128} of PFET 128 is linearly proportional to the tuning voltage: I_{D128}=Vₜᵤₙₑ/R₁₂₄. Resistor 124 can be made as large as noise specifications will permit in order to minimize current consumption. Op-amp 120, PFET 128 and resistor 124 define a multi-pole system that is compensated by resistor 122 and capacitor 126. Voltage-to-current converter 119 linearly converts the analog tuning voltage Vₜᵤₙₑ to a current. It is desirable to maintain linearity across the entire tuning voltage range as maintaining linearity directly affects the overall linearity of the voltage-to-frequency conversion aspect of voltage-controlled ring oscillator 70.

The output of op-amp 120 is also applied to the gate of PFET 150, which serves as first controllable full current source 88 of PTC source 84. As described above with regard to FIG. 5, first controllable full current source 88 provides a current in response to the analog tuning voltage Vₜᵤₙₑ. Similarly, the output of op-amp 120 is also applied to the gate of PFET 130, which serves as second controllable scaled current source 89 of PTC source 84.

Second controllable full current source 90 of PTC source 84 provides a current in response to the digital tuning signal Vₜᵤₙₑ[k]. First controllable scaled current source 91 includes PFETs 132, 134, 136, 138, 140, 142, 144, 146 and 148. Second controllable full current source 90 includes PFETs 152, 154, 156, 158, 160, 162, 164, 166 and 168. PFETs 156, 162 and 168 serve as current source transistors and are indirectly connected to the output of op-amp 120 through PFETs 152, 154, 158, 160, 164 and 166, which serve as switching transistors. These switching transistors operate in pairs in response to the 3-bit digital word k[2:0], which is the same as Vₜᵤₙₑ[k] shown in FIG. 5. The pair of PFETs 152 and 154 are driven by complementary signals k*[0] and k[0], respectively. The pair of PFETs 158 and 160 are driven by complementary signals k*[1] and k[1], respectively. The pair of PFETs 164 and 166 are driven by complementary signals k*[2] and k[2], respectively. Although in the exemplary embodiment second controllable full current source 90 has three current source transistors and associated pairs of switching transistors, in other embodiments such a controllable current source can have any number of current source transistors and any number and arrangement of switching transistors.

Using PFETs 152, 154 and 156 as an example, the operation of controllable current source 90 can be described as follows: When digital signal k[0] is asserted, the gate of PFET 154 is at the supply voltage (VDD) and PFET 154 is therefore off. The digital signal k*[0] is at ground, which switches PFET 152 on, thereby connecting the output voltage of op-amp 120 to the gate of PFET 156. In this state, PFET 156 also behaves as a voltage-controlled current source, and its output current adds to that of PFET 150. Therefore, in the exemplary embodiment the tunable current biasing ring oscillator circuit 72 features both analog and digital controls. Conversely, when k[0] is at ground, PFET 154 is turned on, and the gate of PFET 156 is pulled to VDD, turning PFET 156 off. Simultaneously, k*[0] is at VDD, turning off PFET 152 and breaking the connection between the output of op-amp 120 and the gate of PFET 156. In this state, PFET 156 has no effect on the circuit. PFETs 162 and 168 are similarly controlled by digital signals k[1] and k[2], respectively, through respective PFET pairs.

As PFETs 132-148 are arranged in the same manner and operate in the same manner as described above with regard to PFETs 152-168, the arrangement and operation is not described herein in similar detail. However, while the “full” current that is output by second controllable full current source 90 is provided to ring oscillator circuit 70 as a bias current, the “scaled-down” current that is output by first controllable scaled current source 91 is provided to peak limiter 76 as a bias current. The operation of peak limiter 76 is described below in further detail.

The total output current of PTC source 84 is

$${I}_{tune} ( {V}_{tune} , k ) = α {V}_{tune} ( 1 + \frac{k}{ρ} ) , α = \frac{{w}_{12}}{{w}_{1} R 1} , ρ = \frac{{w}_{12}}{{w}_{15}} . \qquad ( 9 )$$

In equation (9), w refers to (PFET) transistor width, a is the gain or transconductance, p determines the minimum current step, and k is the digital word in decimal. The lengths of PFETs 128, 130, 136, 142, 148, 150, 156, 162 and 168 are equal. (The length and width are those defining the area on the die on which the transistor is formed.)

Like above-described PTC source 84, PFC source 86 includes a voltage-to-current converter 174 comprising an operational amplifier (op-amp) 176, resistors 178 and 180, a capacitor 182, and a PFET 184. Indeed, in the exemplary embodiment the entire structure of PFC source 86 is identical to that of PTC source 88, but op-amp 176 references a fixed or constant bandgap voltage V_{bg} (labeled “Vbg” in FIG. 7 to aid readability), which serves as a reference voltage. Structuring PFC source 86 and PTC source 88 identically provides strong immunity to variations in process, supply voltage and temperature or “PVT.” Op-amp 174, PFET 184 and resistor 180 (the resistance of which can be designated “R₁₈₀”) form a unity gain feedback loop with the drain current of PFET 184, I_{D}=V_{bg}R₁₈₀. Resistor 178 and capacitor 182 compensate the loop. In order to further reduce PVT sensitivity, resistor 178 and resistor 180 can be matched, meaning they can be of identical construction, orientation, aspect ratio, etc. Matching resistors 178 and 180 can help ensure that the ratio of fixed current to tuning current is accurate and the oscillation frequency is correct.

The output of op-amp 174 is also applied to the gates of PFETs 206 and 186, which serve as fixed full current source 94 and fixed scaled current source 95, respectively, of PFC source 86. Fixed current sources 94 and 95 provide currents in response to the bandgap voltage V_{bg} alone and are thus not user-controllable, i.e., their output current is “fixed” in relation to V_{bg}. Controllable full current source 92 of PFC source 86 provides a current in response to the digital tuning signal Vₜᵤₙₑ[j].Controllable scaled current source 93 includes PFETs 188, 190, 192, 194, 196, 198, 200, 202 and 204. Controllable full current source 92 includes PFETs 208, 210, 212, 214, 218, 220, 222 and 224. Of these, PFETs 212, 218 and 224 serve as current source transistors and are indirectly connected to the output of op-amp 176 through PFETs 208, 210, 214, 216, 220 and 222, which serve as switching transistors in the same manner as those of above-described controllable current source 90, operating in pairs in response to the 3-bit digital word j[2:0], which is the same as Vₜᵤₙₑ[j] shown in FIG. 5. As controllable current source 92 operates in the same manner as described above with regard to controllable current source 90, the description of this operation is not repeated in similar detail.

PFETs 186-204 provide a bias current to peak limiter 76 in essentially the same manner as that described above with regard to PFETs 130-148. Likewise, PFETs 206-224 provide a bias current to ring oscillator circuit 72 that is a scaled-down version of the bias current provided to peak limiter 76. The total output current of PFC source 86 is

$${I}_{fixed} ( j ) = β {V}_{bg} ( 1 + \frac{j}{γ} ) , β = \frac{{w}_{33}}{{w}_{22} {R}_{4}} , γ = \frac{{w}_{33}}{{w}_{36}} . \qquad ( 10 )$$

Analogous to equation (8), w refers to (PFET) transistor width, β is the transconductance, determines the minimum current step, and j is the digital word in decimal. The lengths of PFETs 186, 188, 192, 198, 204, 206, 212, 218 and 224 are equal.

An added advantage of the op-amp-based voltage-to-current conversion used in both PTC source 84 and PFC source 86 is excellent power supply rejection. Noise on VDD will be attenuated by gm₁₈₄R₁₂₄A1 and gm₁₈₄R₁₈₀A2 in the PTC and PFC respectively (where gm₁₂₈ and gm₁₈₄ represent the transconductances of PFETs 128 and 184, respectively, and A1 and A2 represent the voltage gains of op-amps 120 and 176, respectively. The magnitude and bandwidth of the suppression is dependent on the op-amp characteristics rather than ring oscillator circuit 72, thus facilitating optimization of power supply rejection independently of other oscillator circuit specifications.

Peak limiter 76, which comprises an op-amp 230 and a PFET 232, improves linearity by holding the oscillation amplitude in ring oscillator circuit 72 constant regardless of the bias current received by ring oscillator circuit 72. The circuitry of peak limiter 76 forms a feedback loop that references a voltage, V_{ref}, to set the amplitude peak and a scaled down copy of the bias current received by ring oscillator circuit 72 to detect tuning changes. This current is generated by PFETs 130-148 in PTC source 84 and PFETs 186-204 in PFC source 86. Op-amp 230 sets the gate terminal voltage of PFET 232 such that its drain terminal voltage is equal to _{V}_{ref}. As the bias current received by ring oscillator circuit 72 varies with the analog tuning voltage Vₜᵤₙₑ and the above-described digital tuning words Vₜᵤₙₑ[j] and Vₜᵤₙₑ[k] the gate bias of PFET 232 adjusts to prevent any voltage change at its source terminal The output of op-amp 176 is also applied to the gates of PFETs 108, 112 and 112, the source terminals of which are connected to ring oscillator nodes 114, 116 and 118, respectively. Because the bias current for peak detector 76 is scaled down from the bias current received by ring oscillator circuit 72, PFETs 108, 110 and 112 can be scaled up from PFET 232 by the same ratio.

As illustrated in FIGS. 8A-D, inverter 78 (PFET 96 and NFET 98) and PFET 108 can conduct over three distinct regions 234, 236 and 238. At time t=0 (FIG. 8A), the gate terminals of PFET 96 and NFET 98 have just transitioned to ground (GND), turning NFET 98 off. Vₓ starts to rise in region 234 as PFET 96 supplies current to capacitance 240, as illustrated in FIG. 8B. PFET 108 is off, as Vₓ<V_{b}+Vₜₕ(PMOS) (where vₜₕ(PMOS) is the triggering threshold of a P-type MOSFET such as PFET 108). Region 236 begins when Vₓ≧V_{b}Vₜₕ(PMOS). PFET 108 will gradually turn on and shunt current that would otherwise be used to charge capacitance 108, as illustrated in FIG. 8C. As Vₓ continues to rise, the conducting strength of PFET 108 increases, siphoning even more current. Region 238 is reached when Vₓ=V_{ref} and PFET 108 becomes capable of conducting the current of PFET 96 in its entirety, preventing any further voltage increase, as illustrated in FIG. 8D.

Tuning voltage changes vary the bias current received by ring oscillator circuit 72, which is mirrored to peak detector 76, allowing peak detector 76 to compensate by automatically adjusting V_{b}. This modulates the conductive strength of PFETs 108, 110 and 112 and forces the oscillation amplitude to remain constant as it is tuned. Furthermore, as PFETs 108, 110 and 112 are only active toward the peak of the cycle, they and the rest of the circuitry of peak limiter 76 contribute little to the overall phase noise of voltage-controlled ring oscillator 70.

The crowbar current of NFET 98 as it begins to turn on toward the peak of Vₓ can also be considered. Because this crowbar current also reduces the total current available to charge capacitance 240, the crowbar current can be accounted for by a slight size reduction in PFETs 108, 110 and 112.

Referring again to FIG. 7, the core of ring oscillator circuit 72 comprises three identical PFETs 96, 100 and 104 and three identical NFETs 98, 102 and 106. Both types of transistors have the same length, and the PFET/NFET width ratio is less than one to produce skewed rise and fall times, as described above. The output can be buffered by an inverter or buffer 242 to reduce oscillator loading. The source terminals of PFETs 96, 100 and 104 are shorted together and driven by the summed currents output by PTC source 84 and PFC source 86.

The above-described architecture or structure of ring oscillator 70 provides linear voltage to frequency conversion as well as a flexible means for selecting combinations of gain and frequency range. Substituting equations (9) and (10) into equation (8), the oscillation frequency is

$${f}_{vco} ( {V}_{tune} , k , j ) = \frac{α {V}_{tune} ( 1 + \frac{k}{ρ} ) + β {V}_{bg} ( 1 + \frac{j}{γ} )}{\frac{3}{2} {V}_{ref} C} . \qquad ( 11 )$$

Note in equation (11) that V_{sw} can be represented by V_{ref} because of the effect of peak limiter 76. The oscillation frequency can be expressed as a function of the analog tuning voltage Vₜᵤₙₑ and the two independent digital tuning signals ₜᵤₙₑ[j] and Vₜᵤₙₑ[k]. The gain of ring oscillator 70 is found by taking the partial derivative of equation (10) with respect to Vₜᵤₙₑ.

$${K}_{vco} ( {V}_{tune} , k ) = \frac{\partial {f}_{osc} ( {V}_{tune} , k )}{\partial {V}_{tune}} = \frac{α ( 1 + \frac{k}{ρ} )}{\frac{3}{2} {V}_{ref} C} . \qquad ( 12 )$$

Equation (12) shows that K_{vco} has no dependence on Vₜᵤₙₑ, indicating completely linear voltage-to-frequency transfer function, as is desirable. In addition, the presence of k allows K_{vco} to be digitally adjusted. Taking the partial derivative of equation (10) with respect to j gives

$${K}_{vco} = \frac{\partial {f}_{osc} ( {V}_{tune} , k , j )}{\partial j} = \frac{\frac{β}{γ} {V}_{bg}}{\frac{3}{2} {V}_{ref} C} . \qquad ( 13 )$$

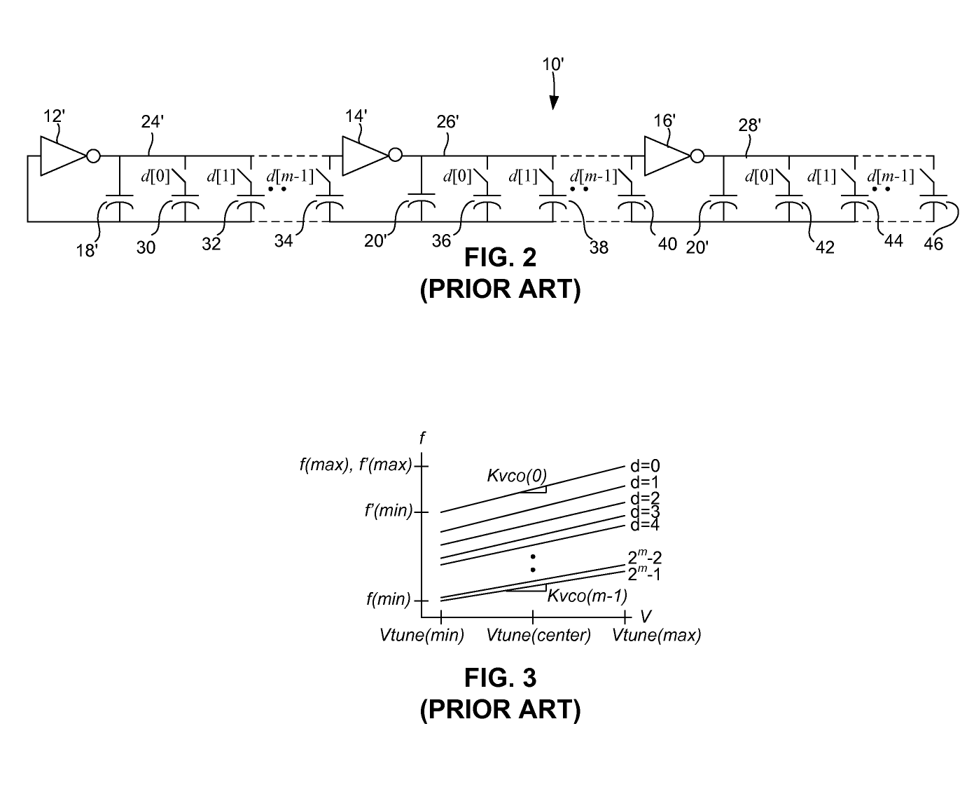

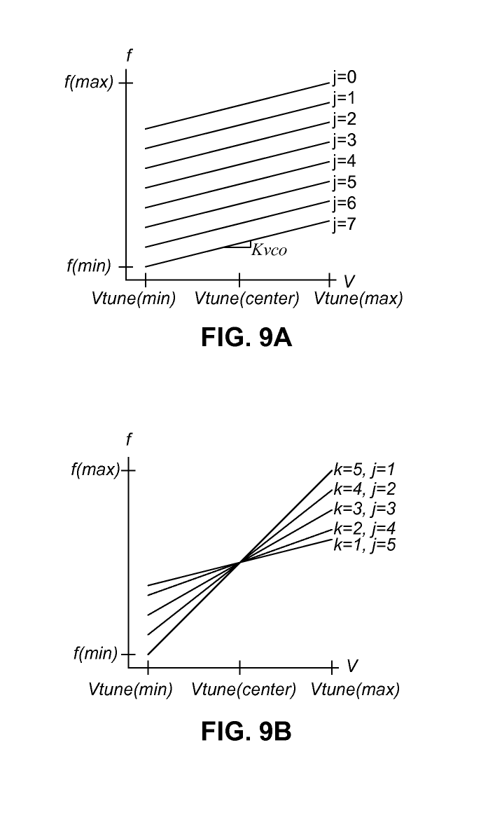

Equation (13) expresses the change in frequency for a least-significant bit (LSB) change in fixed current. Note that j, k and Vₜᵤₙₑ are absent from equation (13), indicating that the tuning curves generated by this architecture are identically spaced, as shown in FIG. 9A. In other words, K_{vco} is constant regardless of j. This is a marked improvement over a variable K_{vco} resulting from, for example, prior switched-capacitor or switched-resistor approaches (FIGS. 2-4).

As illustrated in FIG. 9, voltage-controlled ring oscillator 70 can be operated in a constant gain, uniform digital frequency shift mode by selecting a digital tuning signal Vₜᵤₙₑ[j] while holding the digital value Vₜᵤₙₑ [k] constant. Alternatively, as illustrated in FIG. 9B, voltage-controlled ring oscillator 70 can be operated in a programmable gain mode by selecting both digital tuning signals Vₜᵤₙₑ[j] and Vₜᵤₙₑ[k].

Equations (11), (12) and (13) capture the flexibility of the above-described architecture or structure of voltage-controlled ring oscillator 70. For low and constant K_{vco} along with a wide tuning range, k can be held constant while j is selectable. The family of tuning curves produced from this configuration is shown in FIG. 9A. On the other hand, if variable K_{vco} is needed, then k can be made selectable as well, as shown in FIG. 9B. Gain programming done this way also results in a frequency shift, which a user of voltage-controlled ring oscillator 70 may or may not desire. This frequency shift can be eliminated for any single tune voltage if k and j are adjusted simultaneously and in opposite directions. In addition, PTC and PTF expressions must be linked. For example, if programmable gain is desired independent of frequency at the center of the tuning range, then

$$α / ρ {V}_{tune} ( center ) = β / γ {V}_{bg} . \qquad ( 14 )$$

This equality states that the analog and digital LSBs should be identical when the tuning voltage is in the center of its range. Now, as k is incremented and j is decremented, the gain will increase and the tuning curves will pivot counter clockwise around Vₜᵤₙₑ(center) and vice versa, as shown in FIG. 9B.

The above-described voltage-controlled ring oscillator 70 provides a large oscillator frequency tuning range while maintaining linearity and constant gain. In addition, linearity can be promoted by controlling the charging current, skewing the rise and fall times of the oscillation signal and limiting the peak amplitude of the oscillation signal. The digital configurability or programmability of voltage-controlled ring oscillator 70 also provides a convenient means for adjusting the oscillator gain if desired, with no additional overhead.

While various embodiments of the invention have been described, it will be apparent to those of ordinary skill in the art that many more embodiments and implementations are possible that are within the scope of this invention. Accordingly, the invention is not to be restricted except in light of the following claims.

What is claimed is:

1. A voltage-controlled ring oscillator, comprising:
a bias current generator, the bias current generator comprising one or more controllable current sources, at least one of the controllable current sources generating a portion of the bias current in response to an analog tuning voltage, and at least one other of the controllable current sources generating another portion of the bias current in response to a digitally controlled network of linearly responsive current source transistors; and
a plurality of inverters coupled in a ring with each other and defining an oscillator circuit, each inverter receiving the bias current.

2. The voltage-controlled ring oscillator claimed in claim 1, wherein:
each inverter comprises a P-channel field-effect transistor (PFET) and an N-channel field-effect transistor (NFET), each formed on and occupying an area on an integrated circuit die, a source terminal of each PFET coupled to an output of the bias current generator; and
a ratio of the area occupied by the PFET to the area occupied by the NFET is less than 3:1, wherein the inverter has a delay substantially the same as a delay of an inverter having a PFET and NFET of substantially the same size as each other.

3. The voltage-controlled ring oscillator claimed in claim 1, further comprising a peak limiter coupled to the oscillator circuit and the bias current generator, the peak limiter limiting an oscillation amplitude of the oscillator circuit in response to the bias current.

4. The voltage-controlled ring oscillator claimed in claim 3, wherein the one or more controllable current sources comprises a first controllable current source, the first controllable current source producing a first oscillator bias current in response to the tuning voltage, an output of the first controllable current source coupled to the oscillator circuit to provide the first oscillator bias current to bias the oscillator circuit.

5. The voltage-controlled ring oscillator claimed in claim 4, wherein the one or more controllable current sources further comprises a second controllable current source, the second controllable current source producing a first peak limiter bias current in response to the tuning voltage, an output of the second controllable current source coupled to the peak limiter to provide the first peak limiter bias current to bias the peak limiter, the first peak limiter bias current proportional to the first oscillator bias current.

6. The voltage-controlled ring oscillator claimed in claim 5, wherein the one or more controllable current sources comprises a third controllable current source, the third controllable current source producing a second oscillator bias current in response to a reference voltage, an output of the third controllable current source coupled to the oscillator circuit to provide the second oscillator bias current to further bias the oscillator circuit.

7. The voltage-controlled ring oscillator claimed in claim 6, wherein the one or more controllable current sources further comprises a fourth controllable current source, the fourth controllable current source producing a second peak limiter bias current in response to reference voltage, an output of the fourth controllable current source coupled to the peak limiter to provide the second peak limiter bias current to further bias the peak limiter, the second peak limiter bias current proportional to the second oscillator circuit bias current.

8. The voltage-controlled ring oscillator claimed in claim 1, wherein the bias current generator comprises:
a first substantially linear voltage-to-current converter, the first substantially linear voltage-to-current converter producing a first voltage-to-current converter output current in response to the tuning voltage;
a plurality of first current source transistors, the plurality of first current source transistors producing a first current in response to the first voltage-to-current converter output current, an output of the plurality of first current source transistors coupled to the oscillator circuit to provide the first current to bias the oscillator circuit; and
a plurality of first switching transistors, each controlling one of the first current source transistors in response to a respective bit of a digital control word.

9. The voltage-controlled ring oscillator claimed in claim 8, wherein the bias current generator further comprises:
a second substantially linear voltage-to-current converter, the second substantially linear voltage-to-current converter producing a second voltage-to-current converter output current in response to a reference voltage;
a plurality of second current source transistors, the plurality of second current source transistors producing a second current in response to the second voltage-to-current converter output current, an output of the plurality of second current source transistors coupled to the oscillator circuit to provide the second current to further bias the oscillator circuit; and
a plurality of second switching transistors, each controlling one of the second current source transistors in response to a respective bit of the digital control word.

10. The voltage-controlled ring oscillator claimed in claim 9, wherein:
the voltage-controlled ring oscillator further comprises a peak limiter coupled to the oscillator circuit and the bias current generator, the peak limiter limiting an oscillation amplitude of the oscillator circuit in response to the bias current; and
the bias current generator further comprises:
a third substantially linear voltage-to-current converter, the third substantially linear voltage-to-current converter producing a third voltage-to-current converter output current in response to the tuning voltage;
a plurality of third current source transistors, the plurality of third current source transistors producing a third current in response to the third voltage-to-current converter output current, an output of the plurality of third current source transistors coupled to the peak limiter to provide the third current to bias the peak limiter, the third current proportional to the first current; and
a plurality of third switching transistors, each controlling one of the third current source transistors in response to a respective bit of the digital control word.

11. The voltage-controlled ring oscillator claimed in claim 10, wherein the bias current generator further comprises:
a fourth substantially linear voltage-to-current converter, the fourth substantially linear voltage-to-current converter producing a fourth voltage-to-current converter output current in response to the tuning voltage;
a plurality of fourth current source transistors, the plurality of fourth current source transistors producing a fourth current in response to the fourth voltage-to-current converter output current, an output of the plurality of fourth current source transistors coupled to the peak limiter to provide the fourth current to further bias the peak limiter, the fourth current proportional to the second current; and
a plurality of fourth switching transistors, each controlling one of the fourth current source transistors in response to a respective bit of the digital control word.

12. The voltage-controlled ring oscillator claimed in claim 11, wherein:
the plurality of first switching transistors comprises a plurality of first switching transistor pairs, each pair controlled by one of the respective bits of the digital control word and a complementary bit of the one of the respective bits of the digital control word.

13. A method for operating a voltage-controlled ring oscillator, comprising:
generating a bias current by controlling one or more controllable current sources, at least one of the controllable current sources generating a portion of the bias current in response to an analog tuning voltage, and at least one other of the controllable current sources generating another portion of the bias current in response to a digitally controlled network of linearly responsive current source transistors; and
biasing a plurality of inverters with the bias current, the inverters coupled in a ring with each other to define an oscillator circuit.

14. The method claimed in claim 13, wherein each inverter has a rise time and a fall time, and the rise time and the fall time are substantially unequal to each other.

15. The method claimed in claim 13, further comprising limiting an oscillation amplitude of the oscillator circuit using a peak limiter in response to the bias current.

16. The method claimed in claim 15, wherein:
controlling one or more controllable current sources comprises providing the tuning voltage to a first controllable current source, the first controllable current source producing a first oscillator bias current in response to the tuning voltage; and
biasing the plurality of inverters comprises providing the first oscillator bias current to the oscillator circuit.

17. The method claimed in claim 16, wherein:
controlling the one or more controllable current sources further comprises providing the tuning voltage to a second controllable current source, the second controllable current source producing a first peak limiter bias current in response to the tuning voltage, the first peak limiter bias current proportional to the first oscillator bias current; and
the method further comprises biasing the peak limiter by providing the first peak limiter bias current to the peak limiter.

18. The method claimed in claim 17, wherein:
controlling the one or more controllable current sources comprises providing a reference voltage to a third controllable current source, the third controllable current source producing a second oscillator bias current in response to a reference voltage; and
biasing the plurality of inverters further comprises providing the second oscillator bias current to the oscillator circuit to further bias the oscillator circuit.

19. The method claimed in claim 18, wherein:
controlling the one or more controllable current sources further comprises providing the reference voltage to a fourth controllable current source, the fourth controllable current source producing a second peak limiter bias current in response to reference voltage, the second peak limiter bias current proportional to the second oscillator circuit bias current; and
biasing the peak limiter further comprises providing the second peak limiter bias current to the peak limiter to further bias the peak limiter.
